(19) United States
(12) Patent Application Publication
(10) Pub. No.: US 2023/0223732 A1
(43) Pub. Date: Jul. 13, 2023

(54) LASER DEVICE AND OPTICAL APPARATUS INCLUDING THE SAME

(71) Applicant: Electronics and Telecommunications Research Institute, Daejeon (KR)

(72) Inventors: Dong Hoon SONG, Daejeon (KR); Hong-Seok SEO, Daejeon (KR); Soo Jun PARK, Daejeon (KR); Ho-Youl JUNG, Daejeon (KR); CHUL HUH, Daejeon (KR)

(73) Assignee: Electronics and Telecommunications Research Institute, Daejeon (KR)

(21) Appl. No.: 17/982,652

(22) Filed: Nov. 8, 2022

(30) Foreign Application Priority Data
Jan. 12, 2022 (KR) 10-2022-0004631
Sep. 28, 2022 (KR) 10-2022-0123169

(51) Int. Cl. H01S 3/094; H01S 3/0941; H01S 3/10; H01S 3/11; H01S 3/00; H01S 3/08; G02B 5/10

(52) U.S. Cl. CPC H01S 3/094096; H01S 3/0941; H01S 3/10023; H01S 3/1109; H01S 3/0071; H01S 3/08059; G02B 5/10

(57) ABSTRACT

Provided are a laser device and an optical apparatus including the same. The laser device includes a pump light source configured to provide pump light, a gain medium configured to acquire a gain of seed laser light by using the pump light, a first curved mirror and a second curved mirror, which are provided at both sides of the gain medium to reflect the seed laser light into the gain medium, an output mirror configured to transmit a portion of the seed laser light reflected by the second curved mirror and reflect the other portion of the seed laser light to the gain medium, a first acoustic wave generator connected to the gain medium and configured to provide a first photoacoustic wave in the gain medium, and a second acoustic wave generator connected to the gain medium and configured to provide a second photoacoustic wave in the gain medium.

### CROSS-REFERENCE TO RELATED APPLICATIONS

This U.S. non-provisional patent application claims priority under 35 U.S.C. § 119 of Korean Patent Application Nos. 10-2022-0004631, filed on Jan. 12, 2022, and 10-2022-0123169, filed on Sep. 28, 2022, the entire contents of which are hereby incorporated by reference.

### BACKGROUND

The present disclosure herein relates to an optical apparatus, and more particularly, to a laser device and an optical apparatus including the same.

After the laser apparatus is invented in the 1960s, full-scale studies on the industrial application of the laser apparatus has been began from the 1970s. A CO₂ laser device developed in 1980 is being used in various fields such as industrial, medical, communication, and display fields. A solid laser device such as a diode laser device that is developed later has been used in wider fields than the CO₂ laser device.

### SUMMARY

The present disclosure provides a laser device capable of uniformization and/or homogenizing a beam width of seed laser light, and an optical apparatus including the same.

An embodiment of the inventive concept provides a laser device. The laser device includes: a pump light source configured to provide pump light; a gain medium configured to acquire a gain of seed laser light by using the pump light; a first curved mirror and a second curved mirror, which are provided at both sides of the gain medium to reflect the seed laser light into the gain medium; an output mirror configured to transmit a portion of the seed laser light reflected by the second curved mirror and reflect another portion of the seed laser light to the gain medium; a first acoustic wave generator connected to the gain medium and configured to provide a first photoacoustic wave in the gain medium; and a second acoustic wave generator connected to the gain medium and configured to provide a second photoacoustic wave in the gain medium.

In an embodiment, the gain medium may include vertical electrodes connected to the first acoustic wave generator.

In an embodiment, the vertical electrodes may include: a first vertical electrode disposed on a lower portion of the gain medium; and a second vertical electrode disposed on an upper portion of the gain medium, which faces the first vertical electrode.

In an embodiment, the gain medium may further include horizontal electrodes connected to the second acoustic wave generator and disposed in a direction crossing the first and second vertical electrodes.

In an embodiment, the horizontal electrodes may include: a first horizontal electrode disposed on one sidewall of the gain medium; and a second horizontal electrode disposed on another sidewall of the gain medium.

In an embodiment, the pump light source may include: a first laser diode configured to generate first pump light; a second laser diode configured to generate second pump light having a wavelength greater than that of the first pump light; a third laser diode configured to generate third pump light having a wavelength greater than that of the second pump light; and a fourth laser diode configured to generate fourth pump light having a wavelength greater than that of the third pump light.

In an embodiment, the first pump light may have a wavelength of about 450 nm, the second pump light may have a wavelength of about 465 nm, the third pump light may have a wavelength of about 490 nm, and the fourth pump light may have a wavelength of about 520 nm.

In an embodiment, the laser device may further include: a wave front sensor configured to detect a first wave front of the seed laser light; an adaptive window provided between the pump light source and the first curved mirror and configured to partially adjust a second wave front of the pump light; and a controller connected to the wave front sensor and the adaptive window to distinguish the first wave front of the seed laser light and configured to adjust the second wave front of the pump light in the adaptive window, based on the first wave front.

In an embodiment, the laser device may further include a convex lens disposed between the first curved mirror and the adaptive window to focus the pump light to the gain medium.

In an embodiment, the laser device may further include: a mode locking portion configured to generate a femtosecond pulse of the seed laser light by using mode locking of the seed laser light that is reflected by the first curved mirror; and a first flat mirror provided between the second curved mirror and the wave front sensor.

In an embodiment of the inventive concept, an optical apparatus includes: a source laser device configured to input seed laser light; an amplifying device configured to receive the input seed laser light; and a seed laser device configured to provide seed laser light into the amplifying device so as to generate output laser light. The seed laser device includes: a pump light source configured to provide pump light; a first gain medium configured to acquire a gain of seed laser light by using the pump light; a first curved mirror and a second curved mirror, which are provided at both sides of the first gain medium to reflect the seed laser light into the first gain medium; an output mirror configured to transmit a portion of the seed laser light reflected by the second curved mirror and reflect the other portion of the seed laser light to the first gain medium; a first acoustic wave generator connected to the first gain medium and configured to provide a first photoacoustic wave in the first gain medium; and a second acoustic wave generator connected to the first gain medium and configured to provide a second photoacoustic wave in the first gain medium.

In an embodiment, the amplifying device may include: a first resonant mirror; a second resonant mirror that faces the first resonant mirror; and a second gain medium between the first resonant mirror and the second resonant mirror.

In an embodiment, the amplifying device may further include: a first dichroic mirror configured to transmit the input laser light and reflect the output laser light; and a second dichroic mirror provided between the first resonant mirror and the second gain medium.

In an embodiment, the amplifying device may further include: a first polarizing plate between the first dichroic mirror and the second dichroic mirror; and a second polarizing plate between the first resonant mirror and the second dichroic mirror.

In an embodiment, the amplifying device may further include: a Faraday rotator between the first polarizing plate and the second dichroic mirror; and a modulator between the second polarizing plate and the first resonant mirror.

In an embodiment, the first resonant mirror and the second resonant mirror may include curved mirrors having curvature radii different from each other.

In an embodiment, the amplifying device may further include: a first edge mirror disposed adjacent to the second gain medium to reflect the input laser light to the first resonant mirror; and a second edge mirror configured to receive the output laser light from the second resonant mirror.

In an embodiment, the amplifying device may further include a center mirror between the first edge mirror and the second edge mirror.

In an embodiment, the pump light source may include: a first laser diode configured to generate first pump light; a second laser diode configured to generate second pump light having a wavelength greater than that of the first pump light; a third laser diode configured to generate third pump light having a wavelength greater than that of the second pump light; and a fourth laser diode configured to generate fourth pump light having a wavelength greater than that of the third pump light.

In an embodiment, the first pump light may have a wavelength of about 450 nm, the second pump light may have a wavelength of about 465 nm, the third pump light may have a wavelength of about 490 nm, and the fourth pump light may have a wavelength of about 520 nm.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a block diagram illustrating an example of an optical apparatus according to the inventive concept;

FIG. 2 is a block diagram illustrating an example of a laser device of FIG. 1,

FIG. 3 is a perspective view illustrating an example of a pump light source of FIG. 2;

FIG. 4 is a cross-sectional view illustrating an example of pump light of FIG. 3;

FIG. 5 is a cross-sectional view illustrating an example of a first gain medium of FIG. 2;

FIG. 6 is a graph illustrating an example of a femtosecond pulse of seed laser light generated by a mode locking portion of FIG. 2;

FIG. 7 is a view illustrating positive self-phase modulation, negative self-phase modulation, and balanced self-phase modulation of the femtosecond pulse of FIG. 4;

FIG. 8 is a view illustrating a first wave front of the seed laser light and a second wave front of the pump light of FIG. 2;

FIG. 9 is a block diagram illustrating an example of an amplifying device of FIG. 1; and

FIG. 10 is a block diagram illustrating an example of the amplifying device of FIG. 1.

### DETAILED DESCRIPTION

Embodiments of the present invention will be described in detail with reference to the accompanying drawings. Advantages and features of the present invention, and implementation methods thereof will be clarified through following embodiments described with reference to the accompanying drawings. The present invention may, however, be embodied in different forms and should not be construed as limited to the embodiments set forth herein. Rather, the embodiments introduced herein are provided so that the disclosed contents may be thorough and complete, and the spirit of the present invention may be sufficiently conveyed to those skilled in the art, and the present invention is only defined by the scope of the claims. Like reference numerals refer to like elements throughout.

In the following description, the technical terms are used only for explaining a specific embodiment while not limiting the present invention. In this specification, the terms of a singular form may comprise plural forms unless specifically mentioned. The meaning of ‘comprises’ and/or ‘comprising’ specifies a component, a step, an operation and/or an element does not exclude other components, steps, operations and/or elements. In addition, in the specification, femtoseconds, pulse, self-phase modulation, and mode locking may be understood as meanings mainly used in optical fields. Since it is according to a preferred embodiment, reference numerals presented in the order of description are not necessarily limited to the order.

The contents described above are specific examples for carrying out the embodiment of the inventive concept. The present disclosure will include not only the embodiments described above, but also embodiments that are changeable in design or easily changed. In addition, the present disclosure will also include technologies that are capable of being easily modified and implemented in the future using the foregoing embodiments.

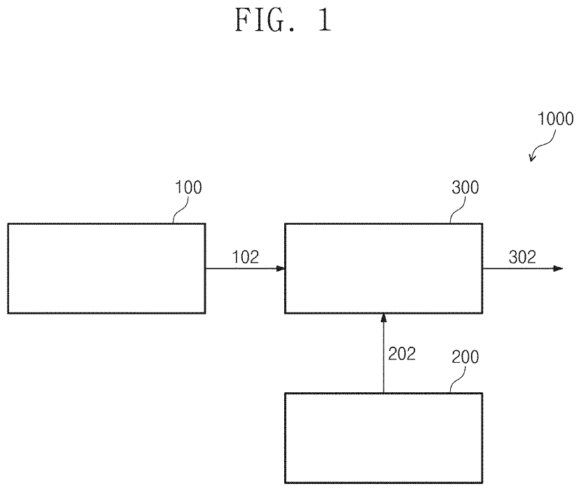

FIG. 1 is a block diagram illustrating an example of an optical apparatus 1000 according to the inventive concept.

Referring to FIG. 1, the optical apparatus 1000 according to the inventive concept may include a laser light amplifying device. According to an example, the optical apparatus 1000 of the inventive concept may include a seed laser device 100, a source laser device 200, and an amplifying device 300. The seed laser device 100 may be connected to the amplifying device 300. The seed laser device 100 may provide the seed laser light 102 to the amplifying device 300. The source laser device 200 may be connected to the amplifying device 300. The source laser device 200 may provide the source laser light 202 to the amplifying device 300. The amplifying device 300 may generate output laser light 302 by amplifying the source laser light 202 using the seed laser light 102. The output laser light 302 may have an intensity greater than that of the source laser light 202. Alternatively, the output laser light 302 may have power greater than that of the source laser light 202.

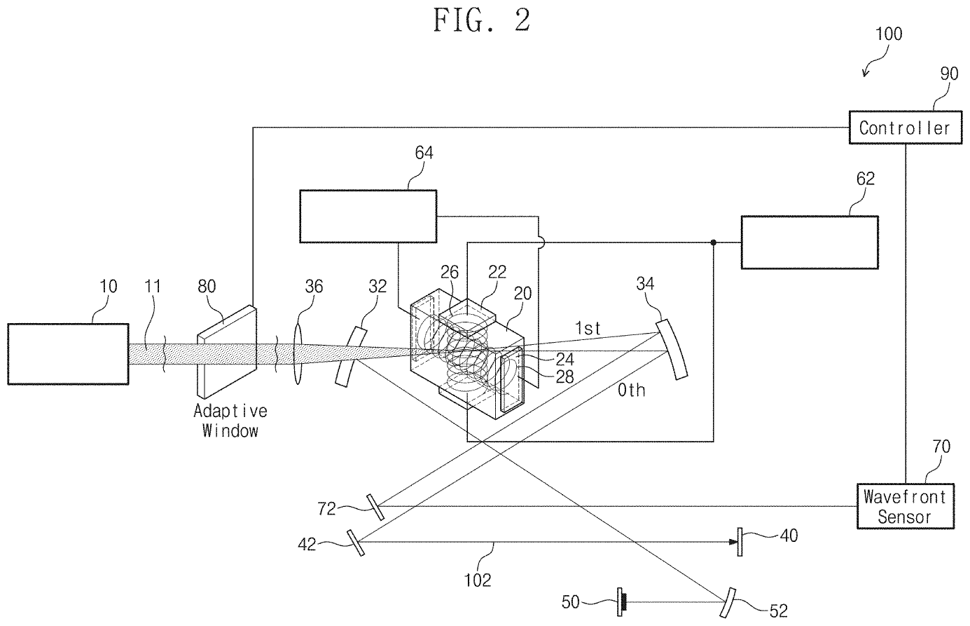

FIG. 2 is a block diagram illustrating an example of the laser device 100 of FIG. 1.

Referring to FIG. 2, the seed laser device 100 may include a femtosecond pulse laser device. For example, the seed laser device 100 may include a pump light source 10, a first gain medium 20, a first curved mirror 32, a second curved mirror 34, an output mirror 40, a mode locking portion 50, a first acoustic wave generator 62, a second acoustic wave generator 64, a wave front sensor 70, an adaptive window 80, and a controller 90. The pump light source 10 may generate pump light 11 to provide the pump light 11 to the first gain medium 20. The first gain medium 20, the first curved mirror 32, the second curved mirror 34, the output mirror 40, the mode locking portion 50, the first acoustic wave generator 62, the second acoustic wave generator 64, the wave front sensor 70, the adaptive window 80, and the controller 90 may function as a resonator that generates the seed laser light 102 using the pump light 11.

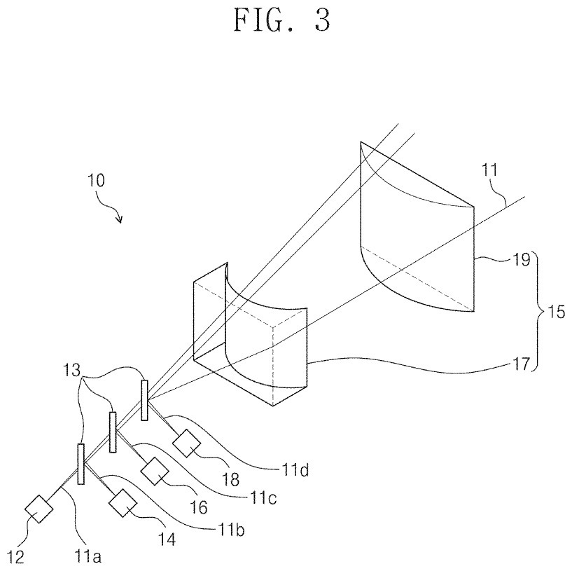

FIG. 3 is a perspective view illustrating an example of the pump light source 10 of FIG. 2.

Referring to FIG. 3, the pump light source 10 may include a first laser diode 12, a second laser diode 14, a third laser diode 16, a fourth laser diode 18, and cylindrical lenses 15.

The first laser diode 12 may generate first pump light 11a. For example, the first pump light 11a may have a wavelength of about 450 nm. The third pump light 11a may include blue seed laser light.

The second laser diode 14 may generate second pump light 11b. The second pump light 11b may have a wavelength greater than that of the first pump light 11a. For example, the second pump light 11b may have a wavelength of about 491 nm. The second pump light 11b may include sky blue seed laser light.

The third laser diode 16 may generate third pump light 11c. The third pump light 11c may have a wavelength greater than that of the second pump light 11b. The third pump light 11c may have a wavelength of about 471 nm. The third pump light 11c may include green blue seed laser light.

The fourth laser diode 18 may generate fourth pump light 11d. The fourth pump light 11d may have a wavelength greater than that of the third pump light 11c. The fourth pump light 11d may have a wavelength of about 471 nm. The fourth pump light 11d may include green seed laser light.

Although not shown, the pump light source 10 may include fifth to n-th laser diodes, but an embodiment of the inventive concept is not limited thereto.

First beam splitters 13 may be provided between the first laser diode 12, the second laser diode 14, the third laser diode 16, and the fourth laser diode 18. The first beam splitters 13 may transmit the first pump light 11a and reflect the second pump light 11b, the third pump light 11c, and the fourth pump light 11d.

The cylindrical lenses 15 may be provided adjacent to one of the first beam splitters 13. The cylindrical lenses 15 may be provided between one of the first beam splitters 13 and the adaptive window 80. The cylindrical lenses 15 may magnify the pump light 11. The pump light 11 may be provided on a sidewall of the first gain medium 20. According to an example, the cylindrical lenses 15 may include a first cylindrical lens 17 and a second cylindrical lens 19.

The first cylindrical lens 17 may be provided between one of the first beam splitter 13 and the second cylindrical lens 19. The first cylindrical lens 17 may include a concave cylindrical lens. The first cylindrical lens 17 may enlarge and/or expand the pump light 11.

The second cylindrical lens 19 may be provided at the other side of the first cylindrical lens 17, which faces the first beam splitters 13. The second cylindrical lens 19 may include a convex cylindrical lens. The second cylindrical lens 19 may collimate the pump light 11.

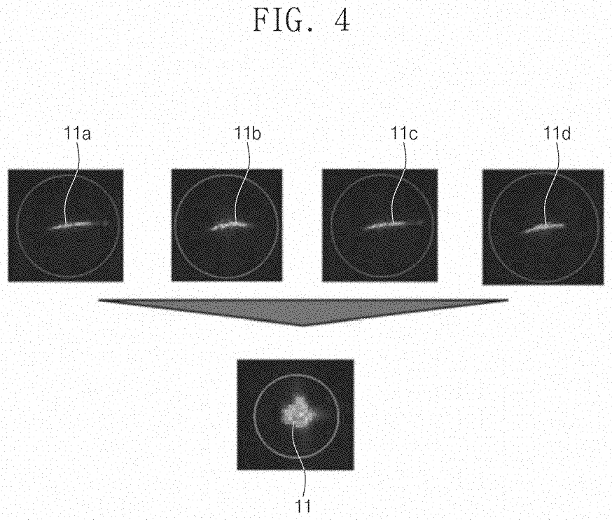

FIG. 4 is a cross-sectional view illustrating an example of the pump light 11 of FIG. 3.

Referring to FIG. 4, each of the first pump light 11a, the second pump light 11b, the third pump light 11c, and the fourth pump light 11d has a transversely elongated beam cross-section, and the pump light 11 may have a circular beam cross-section.

Referring again to FIG. 2, the first gain medium 20 may be provided between the first curved mirror 32 and the second curved mirror 34. The first gain medium 20 may receive the pump light 11 to acquire a gain of seed laser light 102. In addition, the first gain medium 20 may scatter and/or diffract the seed laser light 102. The first gain medium 20 may have a rectangular parallelepiped shape. For example, the first gain medium 20 may include a titanium sapphire crystal.

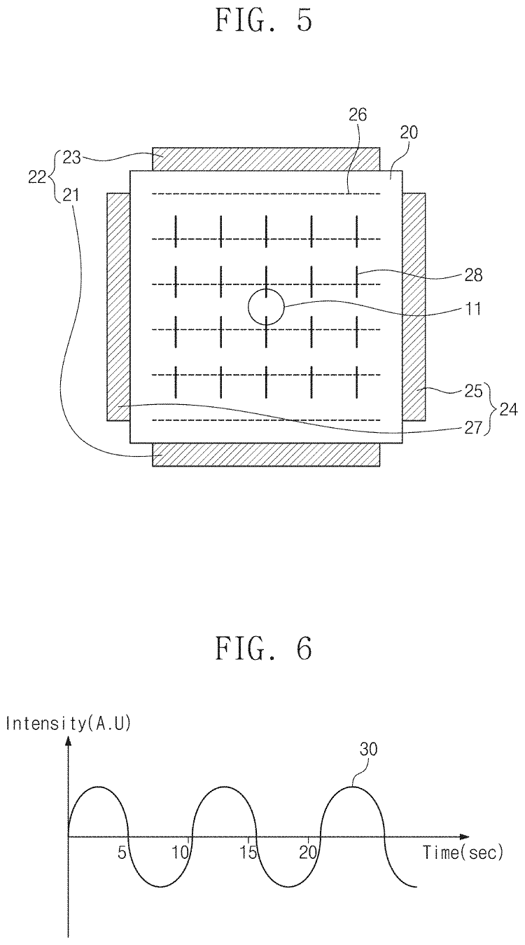

FIG. 5 is a cross-sectional view illustrating an example of the first gain medium of FIG. 2.

Referring to FIG. 5, the first gain medium 20 may have vertical electrodes 22 and horizontal electrodes 24. The vertical electrodes 22 and the horizontal electrodes 24 may provide a first photoacoustic wave 26 and a second photoacoustic wave 28 into the first gain medium 20. Each of the vertical electrodes 22 and the horizontal electrodes 24 may include a metal such as gold (Au), silver (Ag), copper (Cu), aluminum (Al), or tungsten (W).

The vertical electrodes 22 may be provided on bottom and top surfaces of the first gain medium 20. The vertical electrodes 22 may connect the first acoustic wave generator 62 to the first gain medium 20. The vertical electrodes 22 may provide a first photoacoustic wave 26 into the first gain medium 20. According to an example, the vertical electrodes 22 may include a first vertical electrode 21 and a second vertical electrode 23. The first vertical electrode 21 may be provided on a bottom surface of the first gain medium 20. The second vertical electrode 23 may be provided on a top surface of the first gain medium 20. The first photoacoustic wave 26 may be provided between the first vertical electrode 21 and the second vertical electrode 23. The first photoacoustic wave 26 may be displayed as a wave front parallel to the first vertical electrode 21 and the second vertical electrode 23.

The horizontal electrodes 24 may be provided on both surfaces of the first gain medium 20. The horizontal electrodes 24 may connect the second acoustic wave generator 64 to the first gain medium 20. The horizontal electrodes 24 may provide a second photoacoustic wave 28 into the first gain medium 20. According to an example, the horizontal electrodes 24 may include a first horizontal electrode 25 and a second horizontal electrode 27. The first horizontal electrode 25 may be provided on one sidewall of the first gain medium 20. The second horizontal electrode 27 may be provided on the other sidewall of the first gain medium 20, which faces the first horizontal electrode 25. The second photoacoustic wave 28 may be provided between the first horizontal electrode 25 and the second horizontal electrode 27. The second photoacoustic wave 28 may be displayed as a wave front parallel to the first horizontal electrode 25 and the second horizontal electrode 27.

Referring again to FIG. 2, the first curved mirror 32 may be provided at one side of the first gain medium 20. The first curved mirror 32 may transmit the pump light 11 and reflect the seed laser light 102 to the first gain medium 20 and the mode locking portion 50. For example, the first curved mirror 32 may include a dichroic curved mirror.

A first convex lens 36 may be provided between the first curved mirror 32 and the pump light source 10. The first convex lens 36 may focus the pump light 11 onto the first gain medium 20 to improve generation efficiency of the seed laser light 102.

The second curved mirror 34 may be provided at the other side of the first gain medium 20. The second curved mirror 34 may reflect a portion (e.g., 0th-order diffracted light 0th) of the seed laser light 102 to the first gain medium 20 and the output mirror 40. In addition, the second curved mirror 34 may reflect a portion (e.g., 1-order diffracted light 1st) of the seed laser light 102 to the first gain medium 20 and the wave front sensor 70.

The output mirror 40 may transmit a portion of the seed laser light 102 provided from the first gain medium 20, and the output mirror 40 may reflect the other portion of the seed laser light 102 again to the first gain medium 20 to resonate and/or generate the seed laser light 102. For example, the output mirror 40 may include a half mirror, but an embodiment of the inventive concept is not limited thereto.

A first flat mirror 42 may be provided between the output mirror 40 and the second curved mirror 34. The first flat mirror 42 may reflect the seed laser light 102 to the second curved mirror 34 and the output mirror 40.

FIG. 6 is a graph illustrating an example of a femtosecond pulse 30 of the seed laser light 102 generated by the mode locking portion of FIG. 2.

Referring to FIGS. 2 and 6, the mode locking portion 50 may receive the seed laser light 102 to generate the femtosecond pulse 30 of the seed laser light 102. For example, the femtosecond pulse 30 may have a period of about 10.7 nm. The mode locking portion 50 may include a saturated absorber. The saturated absorber may generate the femtosecond pulse 30 of the seed laser light 102 based on mode locking of a non-linear phenomenon. The mode locking may be induced by a non-linear optical Kerr effect. Also, the mode locking portion 50 may include a chirped mirror or a prism, but the embodiment of the inventive concept is not limited thereto. A third curved mirror 52 may be provided between the mode locking portion 50 and the first curved mirror 32. The third curved mirror 52 may reflect the seed laser light 102 to the mode locking portion 50 and the first curved mirror 32.

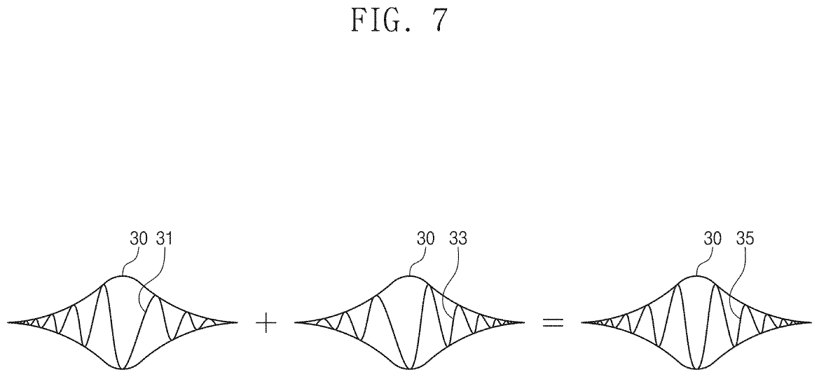

FIG. 7 is a view illustrating positive self-phase modulation 31, negative self-phase modulation 33, and balanced self-phase modulation 35 of the femtosecond pulse 30 of FIG. 4.

Referring to FIGS. 2 and 7, the first gain medium 20 and the mode locking portion 50 may generate the positive self-phase modulation 31 of the seed laser light 102. The positive self-phase modulation 31 may be generated in the pump light source 10, the first convex lens 36, the first curved mirror 32, the first gain medium 20, and the second curved mirror 34, but an embodiment of the inventive concept is not limited thereto. The positive self-phase modulation 31 may be displayed as a shape in which a phase of the seed laser light 102 within the femtosecond pulse 30 is inclined to a right side. In general, the positive self-phase modulation 31 shows that a non-linear optical effect of the seed laser light 102 within the first gain medium 20 and/or the mode locking portion 50 is irregular or non-homogeneous. Although not shown, the first gain medium 20, and the mode locking portion 50 may generate a positive dispersion value of the seed laser light 102.

The first acoustic wave generator 62 and the second acoustic wave generator 64 may be connected to the first gain medium 20. The first acoustic wave generator 62 and the second acoustic wave generator 64 may provide the first photoacoustic wave 26 and the second photoacoustic wave 28 in the first gain medium 20 to adjust the self-phase modulation of the seed laser light 102. The first photoacoustic wave 26 and the second photoacoustic wave 28 may be provided in a direction perpendicular to the pump light 11 and the seed laser light 102. The first photoacoustic wave 26 and the second photoacoustic wave 28 may be provided in both vertical directions within the first gain medium 20. Furthermore, the first photoacoustic wave 26 and the second photoacoustic wave 28 may be provided in all directions within the first gain medium 20. Each of the first photoacoustic wave 26 and the second photoacoustic wave 28 may have an audible frequency of about 20 Hz to about 20,480 Hz (about 20.48 KHz) and an inaudible frequency of about 20 KHz or more. Alternatively, the first photoacoustic wave 26 and the second photoacoustic wave 28 may include photoacoustic waves, but an embodiment of the inventive concept is not limited thereto. For example, the first photoacoustic wave 26 and the second photoacoustic wave 28 may produce the negative self-phase modulation 33 of the seed laser light 102. The negative self-phase modulation 33 may be displayed as a shape in which a phase of the seed laser light 102 within the femtosecond pulse 30 is inclined to a left side. The negative self-phase modulation 33 may compensate the positive self-phase modulation 31 to change the positive self-phase modulation 25 into a balanced self-phase modulation 29. In addition, the photoacoustic wave generator 28 may generate a negative dispersion value of the seed laser light 102 to compensate a positive dispersion value in the first gain medium 20 and the mode locking portion 50 and improve a non-linear optical effect of the seed laser light 102. That is, the first acoustic wave generator 62 and the second acoustic wave generator 64 may provide the first photoacoustic wave 26 and the second photoacoustic wave 28 in the first gain medium 20 to uniformize and/or homogenize the non-linear optical effect of the seed laser light 102.

Thus, the seed laser element 100 may generate the femtosecond pulse 30 having the balanced self-phase modulation 35 of the non-linear optical effect. In addition, the seed laser device 100 may uniformize and/or homogenize a beam width of the seed laser light 102 using the first acoustic wave generator 62 and the second acoustic wave generator 64 that provide the first photoacoustic wave 26 and the second photoacoustic wave 28.

Although not shown, the second acoustic wave generator 64 may include a power supply. The second acoustic wave generator 64 may provide bias power to the horizontal electrodes 24 to generate an electric field in the first gain medium 20. The electric field may modulate the first photoacoustic wave 26, the pump light 11, and the seed laser light 102.

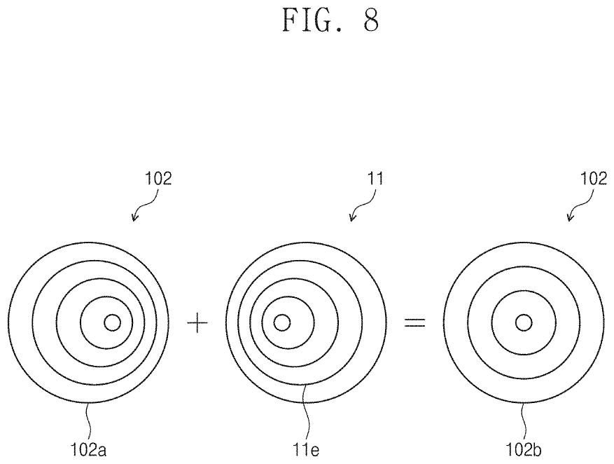

FIG. 8 is a view illustrating a first wave front 102a of the seed laser light and a second wave front 11e of the pump light of FIG. 2.

Referring to FIGS. 2 and 8, the wave front sensor 70 may receive a portion of the seed laser light 102 from the second curved mirror 34 to detect the first wave front 102a. For example, the first wave front 102a may be a right-biased wave front. The wave front sensor 70 may include a CMOS image sensor or a CCD image sensor. Also, the wave front sensor 70 may include a plurality of photodiodes, but an embodiment of the inventive concept is not limited thereto. A second flat mirror 72 may be provided between the wave front sensor 70 and the second curved mirror 34. The second flat mirror 72 may reflect the seed laser light 102 to the wave front sensor 70.

The adaptive window 80 may be provided between the pump light source 10 and the first convex lens 36. The adaptive window 80 may partially control the second wave front 11a of the pump light 11. When the first wave front 102a is the right-biased wave front, the second wave front 11a may be a left-biased wave front. For example, the adaptive window 80 may include a liquid crystal panel.

The controller 90 may be connected to the wave front sensor 70 and the adaptive window 80. The controller 90 may distinguish the first wave front 102a of the seed laser light 102 by using a detection signal of the wave front sensor 70. The controller 90 may control the second wave front 11e of the pump light 11 to adjust the first wave front 102a of the seed laser light 102 into an isotropic wave front 102b.

Thus, the seed laser device 100 may acquire the seed laser light 102 having the isotropic wave front 102b.

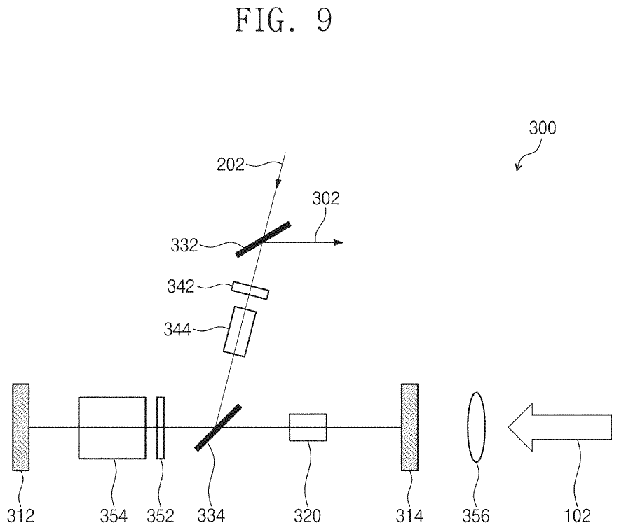

FIG. 9 is a block diagram illustrating an example of the amplifying device 300 of FIG. 1.

Referring to FIG. 9, the amplifying device 300 includes a first resonant mirror 312, a second resonant mirror 314, a second gain medium 320, a first dichroic mirror 332, a second dichroic mirror 334, a first polarizing plate 342, a Faraday rotator 344, a second polarizing plate 352, and a modulator 354.

The first resonant mirror 312 may be provided at one side of the second gain medium 320.

The second resonant mirror 314 may be provided at the other side of the second gain medium 320, which faces the first resonant mirror 312. The seed laser light 102 may pass through the second resonant mirror 314 and be provided into the second gain medium 320. A second convex lens 356 may be provided adjacent to the second resonant mirror 314. The second convex lens 356 may focus the seed laser light 102 onto the second gain medium 320.

The second gain medium 320 may be provided between the first resonant mirror 312 and the second resonant mirror 314. The second gain medium 320 may absorb the seed laser light 102 and the source laser light 202 to acquire a gain of the output laser light 302. The second gain medium 320 may include the same material as the first gain medium 20. For example, the second gain medium 320 may include a titanium sapphire crystal.

The first dichroic mirror 332 may be provided on the second gain medium 320. The first dichroic mirror 332 may transmit the source laser light 202 and reflect the output laser light 302 to the outside.

The second dichroic mirror 334 may be provided between the first resonant mirror 312 and the second gain medium 320. The second dichroic mirror 334 may reflect the source laser light 202 to the first resonant mirror 312 and reflect a portion of the output laser light 302 to the first dichroic mirror 332.

The first polarizing plate 342 may be provided between the first dichroic mirror 332 and the second dichroic mirror 334. The first polarizing plate 342 may include a linear polarizer. For example, the first polarizing plate 342 may include a thin film polarizing plate, but an embodiment of the inventive concept is not limited thereto. The first polarizing plate 342 may convert polarization of the source laser light 202 from p-polarization to s-polarization. The first polarizing plate 342 may convert the polarization of the source laser light 202 from s-polarization to p-polarization.

The Faraday rotator 344 may be provided between the first polarizing plate 342 and the second dichroic mirror 334. The Faraday rotator 344 may include a ferromagnetic crystal, but an embodiment of the inventive concept is not limited thereto. The Faraday rotator 344 may use a magneto-optical effect to allow the source laser light 202 and/or the output laser light 302 to rotate in an azimuthal direction.

The second polarizing plate 352 may be provided between the second dichroic mirror 334 and the first resonant mirror 312. The second polarizer 352 may include a circular polarizer. The second polarizing plate 352 may circularly polarize the source laser light 202 and/or the output laser light 302.

The modulator 354 may be provided between the second polarizing plate 352 and the first resonant mirror 312. The modulator 354 may modulate the source laser light 202 and/or the output laser light 302.

Thus, the amplifying device 300 may acquire the output laser light 302 by using the seed laser light 102 and the source laser light 202.

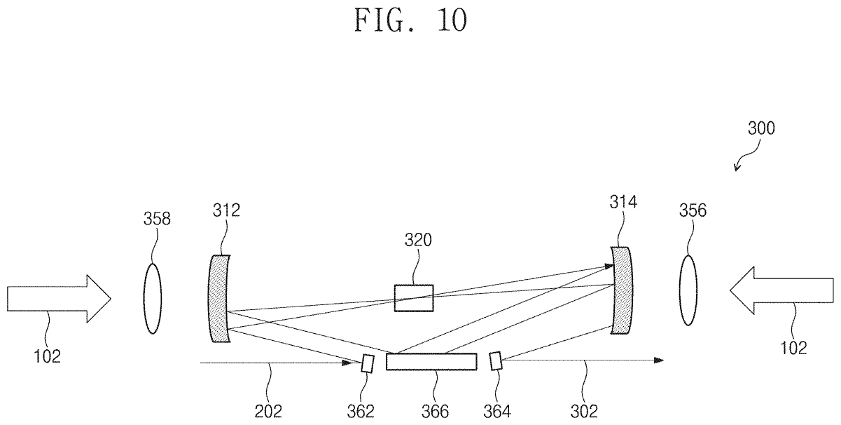

FIG. 10 is a block diagram illustrating an example of the amplifying device 300 of FIG. 1.

Referring to FIG. 10, the first resonant mirror 312 and the second resonant mirror 314 of the amplifying device 300 may include curved mirrors having different curvature radii. For example, the first resonant mirror 312 may have a curvature radius of about 1 m. The second resonant mirror 314 may have a curvature radius of about 0.9 m.

According to an example, the amplifying device 300 may further include a first edge mirror 362, a second edge mirror 364, and a center mirror 366. The first edge mirror 362, the second edge mirror 364, and the center mirror 366 may be provided between the first resonant mirror 312 and the second resonant mirror 314. The first edge mirror 362, the second edge mirror 364, and the center mirror 366 may reflect the source laser light 202 and the output laser light 302.

The first edge mirror 362 may be provided between the first resonant mirror 312 and the center mirror 366. The first edge mirror 362 may reflect the source laser light 202 to the first resonant mirror 312.

The second edge mirror 364 may be provided between the second resonant mirror 314 and the center mirror 366. The second edge mirror 364 may receive the output laser light 302 from the second resonant mirror 314. The second edge mirror 364 may reflect the output laser light 302 to the outside.

The center mirror 366 may be provided between the first edge mirror 362 and the second edge mirror 364. The center mirror 366 may be provided under the second gain medium 320. The center mirror 366 may reflect the output laser light 302 to the first resonant mirror 312 and the second resonant mirror 314. The output laser light 302 may have power greater than that of the source laser light 202.

The second convex lens 356 and the third convex lens 358 may be provided at both edges of the first resonant mirror 312 and the second resonant mirror 314. The second convex lens 356 and the third convex lens 358 may focus the source laser light 202 onto the second gain medium 320.

As described above, the laser device according to the embodiment of the inventive concept may uniformize and/or homogenize the beam width of the seed laser light by using the first and second acoustic wave generators, which provide the first and second acoustic waves in the gain medium.

The contents described above are specific examples for carrying out the embodiment of the inventive concept. The present disclosure will include not only the embodiments described above, but also embodiments that are changeable in design or easily changed. In addition, the present disclosure will also include technologies that are capable of being easily modified and implemented in the future using the foregoing embodiments.

What is claimed is:

1. A laser device comprising:
a pump light source configured to provide pump light;
a gain medium configured to acquire a gain of seed laser light by using the pump light;
a first curved mirror and a second curved mirror, which are provided at both sides of the gain medium to reflect the seed laser light into the gain medium;
an output mirror configured to transmit a portion of the seed laser light reflected by the second curved mirror and reflect another portion of the seed laser light to the gain medium;
a first acoustic wave generator connected to the gain medium and configured to provide a first photoacoustic wave in the gain medium; and
a second acoustic wave generator connected to the gain medium and configured to provide a second photoacoustic wave in the gain medium.

2. The laser device of claim 1, wherein the gain medium comprises vertical electrodes connected to the first acoustic wave generator.

3. The laser device of claim 2, wherein the vertical electrodes comprise:
a first vertical electrode disposed on a lower portion of the gain medium; and
a second vertical electrode disposed on an upper portion of the gain medium, which faces the first vertical electrode.

4. The laser device of claim 3, wherein the gain medium further comprises horizontal electrodes connected to the second acoustic wave generator and disposed in a direction crossing the first and second vertical electrodes.

5. The laser device of claim 4, wherein the horizontal electrodes comprise:
a first horizontal electrode disposed on one sidewall of the gain medium; and
a second horizontal electrode disposed on another sidewall of the gain medium.

6. The laser device of claim 1, wherein the pump light source comprises:
a first laser diode configured to generate first pump light;
a second laser diode configured to generate second pump light having a wavelength greater than that of the first pump light;
a third laser diode configured to generate third pump light having a wavelength greater than that of the second pump light; and
a fourth laser diode configured to generate fourth pump light having a wavelength greater than that of the third pump light.

7. The laser device of claim 6, wherein the first pump light has a wavelength of about 450 nm,
the second pump light has a wavelength of about 465 nm,
the third pump light has a wavelength of about 490 nm, and
the fourth pump light has a wavelength of about 520 nm.

8. The laser device of claim 1, further comprising:
a wave front sensor configured to detect a first wave front of the seed laser light;
an adaptive window provided between the pump light source and the first curved mirror and configured to partially adjust a second wave front of the pump light; and
a controller connected to the wave front sensor and the adaptive window to distinguish the first wave front of the seed laser light and configured to adjust the second wave front of the pump light in the adaptive window, based on the first wave front.

9. The laser device of claim 8, further comprising a convex lens disposed between the first curved mirror and the adaptive window to focus the pump light onto the gain medium.

10. The laser device of claim 8, further comprising:
a mode locking portion configured to generate a femtosecond pulse of the seed laser light by using mode locking of the seed laser light that is reflected by the first curved mirror; and
a first flat mirror provided between the second curved mirror and the wave front sensor.

11. An optical apparatus comprising:
a source laser device configured to input seed laser light;
an amplifying device configured to receive the input seed laser light; and
a seed laser device configured to provide seed laser light into the amplifying device so as to generate output laser light,
wherein the seed laser device comprises:
a pump light source configured to provide pump light;
a first gain medium configured to acquire a gain of seed laser light by using the pump light;
a first curved mirror and a second curved mirror, which are provided at both sides of the first gain medium to reflect the seed laser light into the first gain medium;
an output mirror configured to transmit a portion of the seed laser light reflected by the second curved mirror and reflect the other portion of the seed laser light to the first gain medium;
a first acoustic wave generator connected to the first gain medium and configured to provide a first photoacoustic wave in the first gain medium; and
a second acoustic wave generator connected to the first gain medium and configured to provide a second photoacoustic wave in the first gain medium.

12. The optical apparatus of claim 11, wherein the amplifying device comprises:
a first resonant mirror;
a second resonant mirror that faces the first resonant mirror; and
a second gain medium between the first resonant mirror and the second resonant mirror.

13. The optical apparatus of claim 12, wherein the amplifying device further comprises:
a first dichroic mirror configured to transmit the input laser light and reflect the output laser light; and
a second dichroic mirror provided between the first resonant mirror and the second gain medium.

14. The optical apparatus of claim 13, wherein the amplifying device further comprises:
a first polarizing plate between the first dichroic mirror and the second dichroic mirror; and
a second polarizing plate between the first resonant mirror and the second dichroic mirror.

15. The optical apparatus of claim 14, wherein the amplifying device further comprises:
a Faraday rotator between the first polarizing plate and the second dichroic mirror; and
a modulator between the second polarizing plate and the first resonant mirror.

16. The optical apparatus of claim 12, wherein the first resonant mirror and the second resonant mirror comprise curved mirrors having curvature radii different from each other.

17. The optical apparatus of claim 12, wherein the amplifying device further comprises:
a first edge mirror disposed adjacent to the second gain medium to reflect the input laser light to the first resonant mirror; and
a second edge mirror configured to receive the output laser light from the second resonant mirror.

18. The optical apparatus of claim 17, wherein the amplifying device further comprises a center mirror between the first edge mirror and the second edge mirror.

19. The optical apparatus of claim 11, wherein the pump light source comprises:
a first laser diode configured to generate first pump light;
a second laser diode configured to generate second pump light having a wavelength greater than that of the first pump light;
a third laser diode configured to generate third pump light having a wavelength greater than that of the second pump light; and
a fourth laser diode configured to generate fourth pump light having a wavelength greater than that of the third pump light.

20. The optical apparatus of claim 19, wherein the first pump light has a wavelength of about 450 nm,
the second pump light has a wavelength of about 465 nm,
the third pump light has a wavelength of about 490 nm, and
the fourth pump light has a wavelength of about 520 nm.
